(19) United States
(12) Patent Application Publication
(10) Pub. No.: US 2009/0295613 A1
(43) Pub. Date: Dec. 3, 2009

(54) PERFORMING ANALOG-TO-DIGITAL CONVERSION BY COMPUTING DELAY TIME BETWEEN TRAVELING WAVES IN TRANSMISSION LINES

(75) Inventors: Arjang Hassibi, Austin, TX (US); Ehsan Afshari, Newfield, NY (US); Chaoming Zhang, Austin, TX (US); Jacob Abraham, Austin, TX (US)

Correspondence Address: WINSTEAD PC, P.O. BOX 50784, DALLAS, TX, 75201, US

(73) Assignees: Board of Regents, The University of Texas System, Austin, TX (US); Cornell University, Ithaca, NY (US)

(21) Appl. No.: 12/437,669

(22) Filed: May 8, 2009

Related U.S. Application Data
(60) Provisional application No. 61/056,874, filed on May 29, 2008.

(51) Int. Cl. H03M 1/12

(52) U.S. Cl. 341/155

(57) ABSTRACT

A method and device for converting an analog input electrical signal to a digital signal. A plurality of integrated active and/or passive transmission lines may be implemented with signal-dependant propagation velocities. The delay differences of pulses traveling through these transmission lines are compared, and the collective results are used to evaluate and subsequently quantize the input signal.

### CROSS-REFERENCE TO RELATED APPLICATIONS

This application is related to the following commonly owned co-pending U.S. Patent Application:

Provisional Application Ser. No. 61/056,874, “Performing Analog-to-Digital Conversion by Computing Delay Time Between Traveling Waves in Transmission Lines,” filed May 29, 2008, and claims the benefit of its earlier filing date under 35 U.S.C. § 119(e).

### TECHNICAL FIELD

The present invention relates to analog-to-digital conversion, and more particularly to performing analog-to-digital conversion by computing the delay time between traveling waves in transmission lines.

### BACKGROUND OF THE INVENTION

An analog-to-digital converter (ADC) system converts an input analog voltage or current to a digital value. The digital output value may adopt different coding schemes, such as binary, Gray code or two's complement binary, yet each digital code is always associated with a defined voltage region of the analog input.

The process of converting an analog signal to a digital (or quantized) representation is carried out by sequential, parallel, or a combination of sequential and parallel analog voltage comparisons in which the unknown input signal is compared to a plurality of predefined signals. By analyzing the outcome of the comparisons in ADCs, one can determine which voltage region the input signal belongs to, and accordingly represent that with a specific digital code. Traditionally, electronic ADCs used in electronic systems implement circuit topologies to compare voltage levels and create digital bits which are later processed by digital signal processing blocks (DSP) to create the desired output digital codes.

Today, the explosive growth in wireless and wireline communications is the dominant driver for higher performance ADCs. New applications in wireless communications support multi-mode operations, utilize large portions of bandwidth, such as in the case of ultra wideband (UWB) and 60-GHz-band systems, or attempt to re-use the already licensed spectrum, thus requiring a high dynamic range for operation. Similarly, new applications in wireline communication systems may extend the signal constellations to increase the data throughput, such as in the case of 10-Gb/s Ethernet or next-generation cable modems. These applications are driving the demand for high-resolution, high-speed, low power, and low cost integrated ADCs.

As a result of the demand for high-resolution, high-speed, low power, and low cost integrated ADCs, there has been a focus on scaling the devices used in ADCs to smaller dimensions thereby consuming less power while achieving a higher level of integration. Technology scaling has traditionally been geared towards improving the performance and speed of digital signal processing blocks (i.e., digital circuitry as opposed to analog) and significantly reducing the cost of digital logic and memory. Concurrently, there is an increased interest in using transistors with minimum possible dimensions to implement analog functions, because the improved device transition frequency, f_{T}, allows for faster operation. However, scaling adversely affects most other parameters relevant to analog designs, and ADC systems are no exception.

For example, as the dimensions of transistors used to implement analog functions decrease, the supply voltage decreases thereby lowering the allowable voltage swings in analog circuits. As a result of the low voltage swings, the signal to noise ratio becomes limited and causes the background noise to be more obtrusive. Further, the intrinsic voltage gain of devices is one important gauge of device performance for precision analog designs, and as scaling continues, it keeps decreasing due to a lower output resistance as a result of drain-induced barrier lowering (DIBL) and hot carrier impact ionization.

Thus, there are several limitations in converting analog signals to digital values as the devices used in ADCs continue to be scaled smaller in size.

### BRIEF SUMMARY OF THE INVENTION

In one embodiment of the present invention, a method for converting an analog signal into a digital value comprises generating a first pulse to travel through a first transmission line, where the first transmission is a variable-delay transmission line, where the propagation velocity of the first pulse is variable-delayed as a function of an input signal. The method further comprises generating a second pulse to travel through a second transmission line, where a propagation velocity of the second pulse is independent of the input signal. Furthermore, the method comprises comparing a difference in time between the first pulse and the second pulse traveling through the first and second transmission lines, respectively, at a plurality of locations along the first and second transmission lines. Additionally, the method comprises detecting a delay when the time difference between the first pulse and the second pulse exceeds a threshold. Further, the method comprises determining an input voltage based on the delay using a linear transfer function. The method additionally comprises converting the input voltage to a digital value.

In another embodiment of the present invention, a device for converting an analog signal into a digital value comprises a first transmission line, where a first pulse travels through the first transmission line, where the first transmission is a variable-delay transmission line, where a propagation velocity of the first pulse is variable-delayed as a function of an input signal. The device further comprises a second transmission line, where a second pulse travels through the second transmission line, where a propagation velocity of the second pulse is independent of the input signal. Furthermore, the device comprises a plurality of comparators coupled to the first and second transmission lines at a plurality of locations along the first and second transmission lines, where the plurality of comparators compare a difference in time between the first pulse and the second pulse traveling through the first and second transmission lines, respectively, at the plurality of locations along the first and second transmission lines. Additionally, the device comprises circuitry for detecting a delay when the time difference between the first pulse and the second pulse exceeds a threshold. Furthermore, the device comprises circuitry for determining an input voltage based on the delay.

The foregoing has outlined rather generally the features and technical advantages of one or more embodiments of the present invention in order that the detailed description of the present invention that follows may be better understood. Additional features and advantages of the present invention will be described hereinafter which may form the subject of the claims of the present invention.

### BRIEF DESCRIPTION OF THE SEVERAL VIEWS OF THE DRAWING

A better understanding of the present invention can be obtained when the following detailed description is considered in conjunction with the following drawings, in which:

FIG. 1 illustrates a general architecture of an analog-to-digital converter enabled by active and/or passive variable delay transmission lines in accordance with an embodiment of the present invention;

FIG. 2 depicts the difference between a reference wave and a signal-dependent wave as a function of time in accordance with an embodiment of the present invention;

FIG. 3 illustrates a passive and planar variable-delay transmission line which incorporates shunt varactors as input-dependent electronic components in accordance with an embodiment of the present invention;

FIG. 4 illustrates an active variable-delay transmission line using a plurality of cascaded active delay components in accordance with an embodiment of the present invention;

FIG. 5 illustrates detecting delay differences using XOR and D flip-flop digital systems in accordance with an embodiment of the present invention;

FIG. 6 illustrates an architecture of an ADC converter with a variable-delay active delay line in accordance with an embodiment of the present invention;

FIG. 7 illustrates an embodiment of the present invention of an architecture of an ADC converter;

FIG. 8 illustrates a circuit topology of an N-block and a P-block voltage-dependent variable delay block in accordance with an embodiment of the present invention;

FIG. 9 illustrates interleaved N-blocks and P-blocks forming a voltage-controlled variable-delay transmission line in accordance with an embodiment of the present invention;

FIG. 10 illustrates input-delay transfer functions of a voltage-controlled variable-delay transmission line in accordance with an embodiment of the present invention;

FIG. 11 illustrates an architecture of a delay comparator in accordance with an embodiment of the present invention;

FIG. 12 is a die photo of an ADC system built using a standard 0.13 μm digital CMOS process in accordance with an embodiment of the present invention;

FIG. 13A depicts a graph illustrating the differential of the ADC system of FIG. 7 in accordance with an embodiment of the present invention;

FIG. 13B depicts a graph illustrating the integral nonlinearity of the ADC system of FIG. 7 in accordance with an embodiment of the present invention;

FIG. 14 depicts a graph illustrating the dynamic performance of the ADC system of FIG. 7 in accordance with an embodiment of the present invention; and

FIG. 15 is a flowchart of a method for converting an analog signal into a digital value in accordance with an embodiment of the present invention.

### DETAILED DESCRIPTION OF THE INVENTION

The present invention comprises a method and a device for converting an analog signal into a digital value using active and/or passive variable delay transmission lines. In one embodiment of the present invention, the quantization of an analog input electrical signal is accomplished by modulating parametrically the propagation constant of a traveling electronic wave with the input signal. In one example, the velocity of the electromagnetic traveling wave can be altered by changing the dielectric and/or magnetic properties of the medium in which the wave is propagating. In another example where the traveling wave is an electrical pulse in an electronic transmission line, the propagation velocity can be modified by altering the distributed capacitance of the system using input-dependant variable capacitors, such as accumulation mode variable capacitors (varactors). In an alternative example, where the traveling wave is propagating through an active transmission line, such as inverter amplifier chain, the characteristics of the active components can be modified thereby resulting in a change in overall propagation velocity. Subsequently, at a plurality of coordinates within the path of the traveling wave, the arrival time of the traveling wave is compared to a reference waveform. The aggregate results of these comparisons are then used to estimate the voltage level of the input signal.

In the following description, numerous specific details are set forth to provide a thorough understanding of the present invention. However, it will be apparent to those skilled in the art that the present invention may be practiced without such specific details. In other instances, well-known circuits have been shown in block diagram form in order not to obscure the present invention in unnecessary detail. For the most part, details considering timing considerations and the like have been omitted inasmuch as such details are not necessary to obtain a complete understanding of the present invention and are within the skills of persons of ordinary skill in the relevant art.

In contrast to comparing voltage levels in traditional ADCs, embodiments of the present invention compare the time difference between different traveling waves. By comparing the time difference between different traveling waves, the analog-to-digital conversion process becomes more power efficiently, especially in integrated ADCs built using different semiconductor substrates (e.g., silicon CMOS, SiGe CMOS, silicon BiCMOS, and SiGe BiCMOS processes). This advantage is particularly important in deep sub-micron integrated circuit processes. These processes are optimized for digital signals, where delay and timing are more imperative rather than voltage levels. Accordingly, the systems built using such processes can process and/or compare and/or analyze timing much more robustly than voltage levels. In addition, certain digital circuit families consume extremely small static power compared to voltage amplifiers used in voltage comparison architectures. Another advantage of comparing the time difference between different traveling waves instead of comparing voltage levels is scalability. It is known in the art that the performance of voltage comparison circuitry in integrated circuits is affected perversely by fabrication process scaling; however, timing comparison is not affected and moreover becomes even more power efficient.

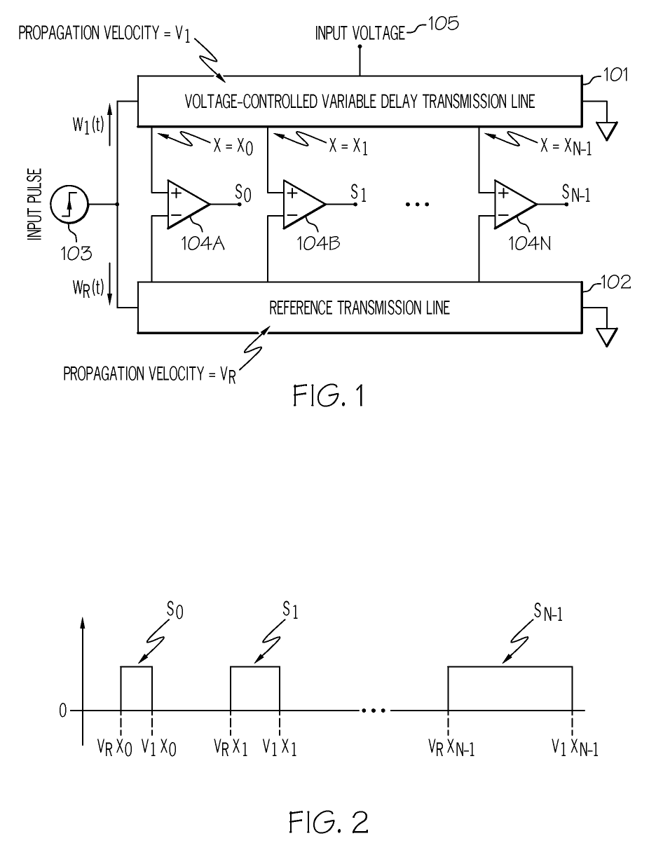

FIG. 1 illustrates a general architecture of an analog-to-digital converter enabled by active and/or passive variable delay transmission lines in accordance with an embodiment of the present invention. Referring to FIG. 1, an input pulse 103 travels through a variable-delay transmission line 101 (indicated as “W₁(t)” in FIG. 1) and a reference transmission line 102 (indicated as “W_{R}(t)” in FIG. 1) simultaneously. The propagation velocity of the pulse in variable-delay transmission line 101, V₁, is a function of input signal 105, while the propagation velocity in reference line 102, V_{R}, is signal-independent. Subsequently, the pulse arrival at different coordinates within the system (e.g., X=X₀, X₁, . . . , X_{N-1}), denoted by s₀, s₁, . . . , s_{N-1}, output of amplifiers 104A-N, becomes a function of input voltage 105 for the wave propagating in variable-delay transmission line 101, while the pulse arrival to the same coordinate for reference transmission line 102 remains constant and input-independent.

As shown in FIG. 2, FIG. 2 depicts the difference between a reference wave and a signal-dependent wave as a function of time in accordance with an embodiment of the present invention. Referring to FIG. 2, in conjunction with FIG. 1, the difference in timing of the signals traveling through variable-delay transmission line 101 and reference transmission line 102 at coordinates X=X₀, X₁, . . . , X_{N-1}, denoted by s₀, s₁, . . . , S_{N-1}, is computed as a function of V₁ and V_{R}. FIG. 2 illustrates that the width of the pulses contain information about input signal 105 through the relationship of V₁ with input signal 105. In one embodiment, the input signal is an analog voltage or current. Accordingly, using the example architecture of FIG. 1, the detection of an input voltage or current has been translated to the detection of a time delay. It is known in the art that the detection of delay is more power efficient in integrated systems, particularly in integrated systems which include digital logic gates.

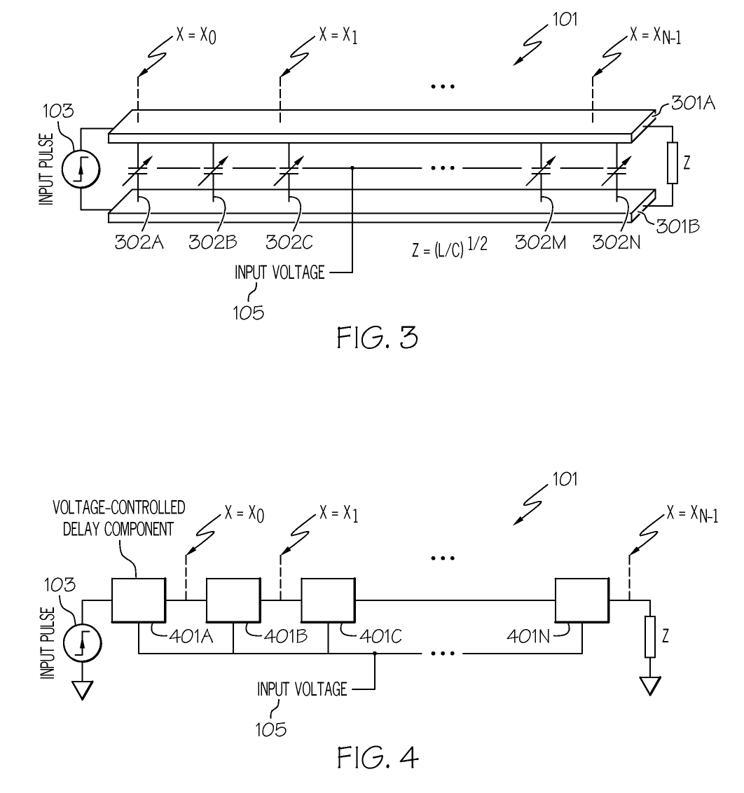

In one embodiment of the present invention, the variable-delay transmission line 101 of FIG. 1 is created using passive transmission lines 301A-B with shunt input-dependant electrical elements as illustrated in FIG. 3. FIG. 3 illustrates variable-delay transmission line 101 of FIG. 1 incorporating shunt varactors 302A-N as input-dependent electronic components in accordance with an embodiment of the present invention. Passive transmission lines 301A-B may collectively or individually be referred to as passive transmission lines 301 or passive transmission line 301, respectively. Shunt varactors 302A-N may collectively or individually be referred to as shunt varactors 302 or shunt varactor 302, respectively. Variable-delay transmission line 101 may include any number of shunt varactors 302. As illustrated in FIG. 3, the shunt elements are varactors. The propagation velocity of electromagnetic waves in this structure is a function of the value of the shunt capacitance which is signal-dependant. As further illustrated in FIG. 3, the impedance (indicated as “Z”) of variable-delay transmission line 101 is a function of the inductance (indicated as “L”) and the capacitance (indicated as “C”) of shunt varactors 302 as indicated in the following formula:

Z=(L/C)^{1/2}

In related embodiments, passive transmission lines 301 are included as an allied component of integrated systems and/or shunt electronic components 302 are active and/or passive devices existing in the integrated systems. Examples of fabrication processes include but are not limited to the following: silicon CMOS, SiGe CMOS, silicon BiCMOS, and SiGe BiCMOS processes.

In other related embodiments, the propagation velocity of the wave in passive transmission line 101 is designed to vary within transmission line 101 to create a desired relationship between the input signal and the velocity of propagation at different regions of passive transmission line 101.

In other related embodiments, transmission line 101 is a tapered transmission line. A tapered transmission line is an inhomogeneous transmission line where the value of inductors and/or capacitors vary in space. It is known in the art that a tapered transmission line can control the shape of the input pulse and the amount of the dispersion. As a result, it is possible to conserve the shape of the input pulse as it propagates along transmission line 101.

In one embodiment, the traveling wave can go through transmission line 101 with segments which have either signal-dependant, or signal-independent propagation velocities. For example, there may be a two-segment series transmission line where only the first part of the transmission line has a propagation velocity which is controlled by the input signal while the other part of the transmission line has a constant propagation velocity.

In another embodiment, variable-delay transmission line 101 is created using active transmission lines with a plurality of cascaded active delay components. The delay components may be created using active electronic devices, such as CMOS MOSFET, Bipolar, and JFET transistors. FIG. 4 illustrates an active variable-delay transmission line using a plurality of cascaded active delay components 401A-N in accordance with an embodiment of the present invention. Active delay components 401A-N may collectively or individually be referred to active delay components 401 or active delay component 401, respectively. As illustrated in FIG. 4, variable delay transmission line 101 of FIG. 1 may comprise a cascade of active delay components 401 that are input-dependent.

In one embodiment, the active transmission lines of variable-delay transmission line 101 are included as an allied component of integrated systems. Some example fabrication processes to create the integrated systems include but are not limited to the following: silicon CMOS, SiGe CMOS, silicon BiCMOS, and SiGe BiCMOS processes.

In other embodiments, the delay components are created using digital logic gates. Examples of such logic gates include, but are not limited to the following: NMOS, static CMOS, dynamic, Domino, Zipper Domino, Differential, and Post-Charge logic.

In other embodiments, the delay difference between the two active and/or passive variable-delay transmission lines is detected using digital circuits.

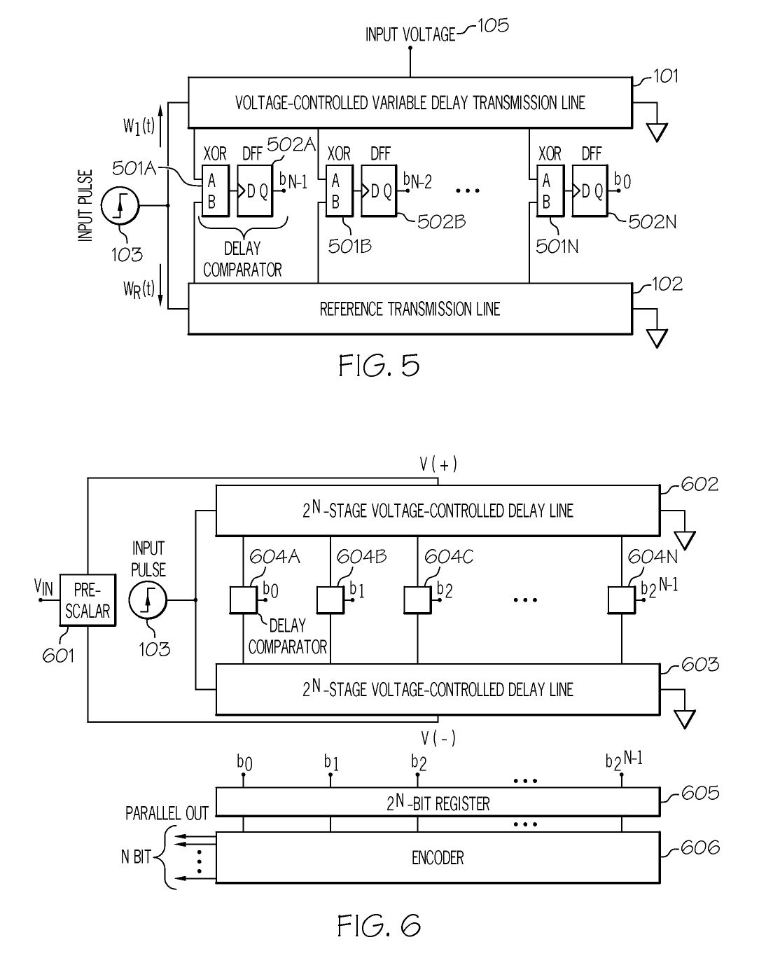

In other embodiments, the output of the delay comparison block is a digital signal and represents a certain delay range. An example of such a comparator is a digital circuit which reports a binary logic of 1 when the delay is more than some predefined value (i.e., a threshold) and a zero when it is otherwise. As an example, the delay may be from 10 fsec to 10 ms, but typically the delay may be in the range of 1 psec to 100 μsec. FIG. 5 illustrates detecting delay differences using XOR 50A-N and D flip-flop 502A-N digital systems in accordance with an embodiment of the present invention. XORs 501A-N (indicated as “XOR” in FIG. 5) may collectively or individually be referred to as XORs 501 or XOR 501, respectively. D flip-flops 502A-N (indicated as “DFF” in FIG. 5) may collectively or individually be referred to as D flip-flops 502 or D flip-flop 502, respectively. As illustrated in FIG. 5, depending on the delay difference (basically the hold-on time of the digital gates within XOR 501 and D flip-flop 502), the output of each step (indicated as “b_{N-1} . . . b₀” in FIG. 5) can be zero or a binary logic of one. The output in this example system has a “thermometer” digital code, which basically converts the analog input to a digital signal. A “thermometer” digital code may refer to continuously outputting a binary logic of one once the delay difference exceeds a threshold. Prior to the delay difference exceeding the threshold, the output is zero.

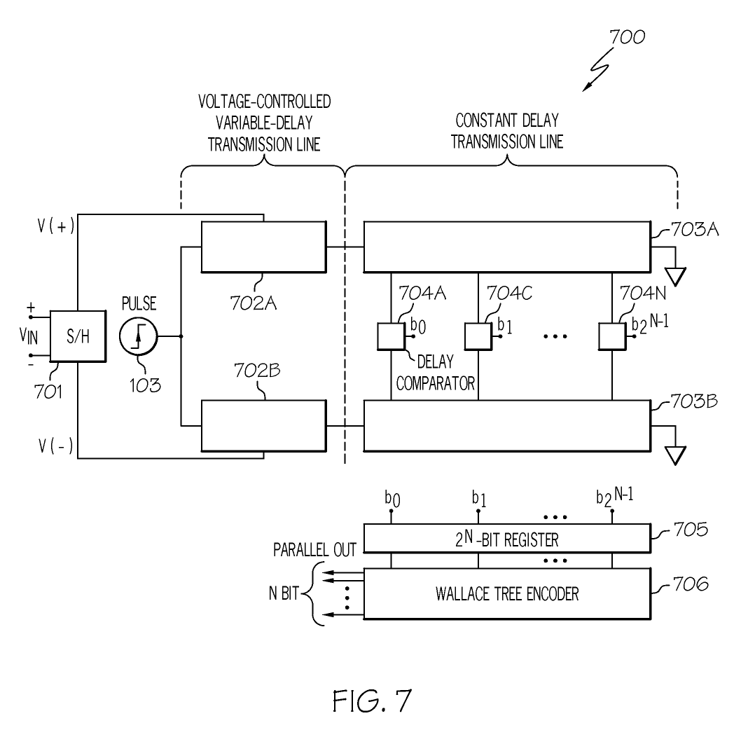

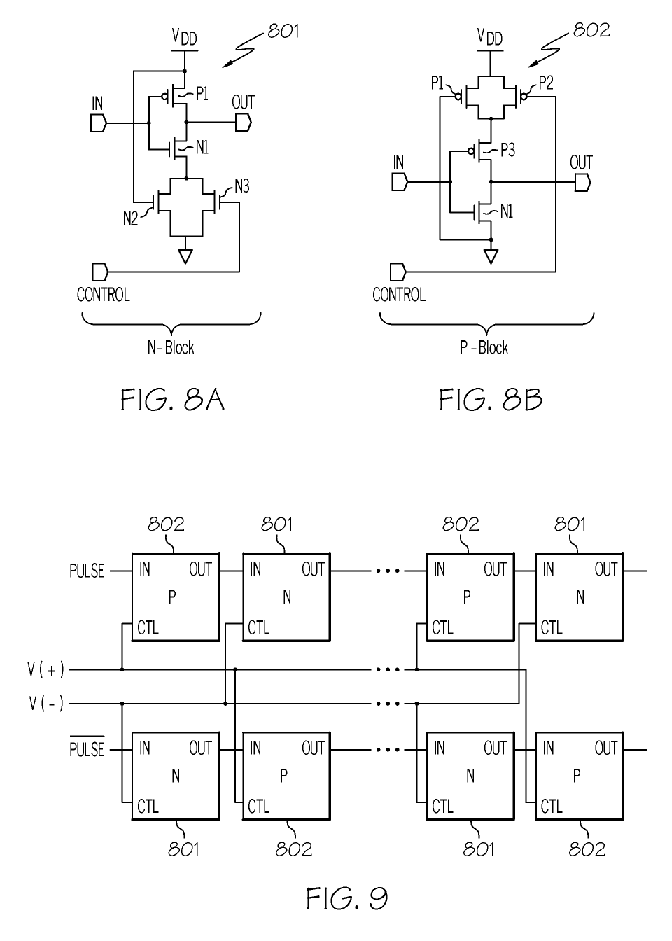

In other embodiments, input signal 105 is applied with reverse polarity to two variable delay transmission lines. In these differential arrangements, the delay variation is created by slowing the propagation velocity in one transmission line, while increasing the velocity in the other. In such embodiments, the reference path is no longer necessary. Another advantage of this implementation is that it reduces the length of the transmission line which is necessary to create the required delay in each comparator. An example of such an implementation is illustrated in FIG. 6. FIG. 6 illustrates an architecture of an ADC 600 with a variable-delay active delay line in accordance with an embodiment of the present invention.

Referring to FIG. 6, a pre-scalar circuitry 601 is implemented to project the range of input signal 105 into the desired differential range required for voltage-controlled delay transmission lines 602, 603. The delay between the traveling waves in voltage-controlled delay transmission lines 602, 603 is determined by delay comparators 604A-N. Delay comparators 604A-N may collectively or individually be referred to as delay comparators 604 or delay comparator 604, respectively. The results of the comparison (indicated as “b₀ . . . b₂^{N-1}” in FIG. 6) are stored in register 605 which may later be encoded by encoder 606 and outputted.

In one embodiment, input signal 105 is initially sampled and held for the duration of the analog-to-digital conversion. There are many sample and hold circuits configured to perform such a procedure, which is known in the art.

An example of using the embodiment of FIG. 6 to convert an analog signal to a digital value is discussed below in connection with FIGS. 7-14. The system described below shows the advantages of using the principles of the present invention both in terms of power performance and compatibility with sub-micron semiconductor fabrication processes.

The following example describes a reduced-to-practice analog-to-digital conversion based on the aforementioned description. FIG. 7 illustrates an embodiment of the present invention of an architecture of an ADC 700 (i.e., the implemented system). ADC 700 includes a sample and hold circuit 701 configured to sample and hold the input signal value steady for a short period of time while the converter performs the following operations that takes a little time. The input voltage signal is initially sampled differentially by sample and hold circuit 701. The sampled differential signal set the delays of two variable delay active transmission lines 702A-B. Transmission lines 702A-B may collectively or individually be referred to as transmission lines 702 or transmission line 702, respectively. In one case, it increases the speed and reduces the delay, while in the other case, it decreases the speed and increases the delay. After the generation of an input-dependant differential delay on the two pulses, the pulses travel through two constant delay transmission lines 703A-B with different propagation velocities. Transmission lines 703A-B may collectively or individually be referred to as transmission lines 703 or transmission line 703, respectively. ADC 700 functions similarly to a time-domain vernier by gradually increasing the overall delay difference of the two pulses. In the example of ADC 700 being a 6-bit ADC, the delay difference between the traveling waves in transmission lines 702, 703 is compared at 63 locations on these two transmission lines 702, 703 by delay comparators 704A-N, where N is 63. Delay comparators 704A-N may collectively or individually be referred to as delay comparators 704 or delay comparator 704, respectively. In this example, if the delay is greater than 120 ps, the output of delay comparator 704 (indicated as “b₀ . . . b₂^{N-1}” in FIG. 7) is the digital value of 1; otherwise, the output of delay comparator is 0. The collective output of all comparators 704 is stored in register 705 which resembles a thermometer code (discussed above) representing the delay. The thermometer code may be further encoded into a binary code by an encoder 706 (e.g., Wallace tree encoder).

Once the delay is represented in the digital realm (e.g., binary code), the input voltage may be determined based on the delay using a linear transfer function (e.g., voltage to delay transfer function which specifies the overall linearity of the system). A further discussion of the linear transfer function is provided below.

Referring to the voltage-controlled variable-delay transmission lines 702 of ADC 700 of FIG. 7, in order to keep the overall linearity specifications of the system within the required range, a series of delay lines may be used in transmission lines 702, where each delay line partially contributes to the overall delay. For example, there may be two delay building blocks in the system which are illustrated in FIG. 8. FIG. 8 illustrates a circuit topology of an N-block 801 and a P-block 802 voltage-dependent variable delay block in accordance with an embodiment of the present invention.

In one embodiment, N-block 801 includes a p-type transistor (indicated as “P1” in FIG. 8) whose drain is connected to the drain of an n-type transistor (indicated as “N I” in FIG. 8). The input of N-block 801 is coupled to the gates of transistors P1, N1. The output of N-block 801 is coupled to the drains of transistors P1, N1. Further, N-block 801 includes n-type transistors (indicated as “N2” and “N3” in FIG. 8) where the gate of transistor N2 is coupled to the voltage source, V_{DD}. The gate of transistor N3 is coupled to a control signal (indicated as “Control” in FIG. 8. Furthermore, the sources of transistors N2, N3 are coupled to ground and the drains of transistors N2, N3 are coupled to the source of transistor N1.

In one embodiment, P-block 802 includes p-type transistors (indicated as “P1” and “P2” in FIG. 8) whose sources are connected to the voltage source, V_{DD}. The gate of transistor P1 is coupled to ground. The gate of transistor P2 is coupled to a control signal (indicated as “Control” in FIG. 8). The drains of transistors P1, P2 are coupled to the source of a p-type transistor (indicated as “P3” in FIG. 8). The drain of transistor P3 is coupled to the drain of an n-type transistor (indicated as “N1” in FIG. 8). The gates of transistors P3, N1 are coupled to the input of P-block 802. The drains of transistors P3, N1 are coupled to the output of P-block 802. The source of transistor N1 is coupled to ground.

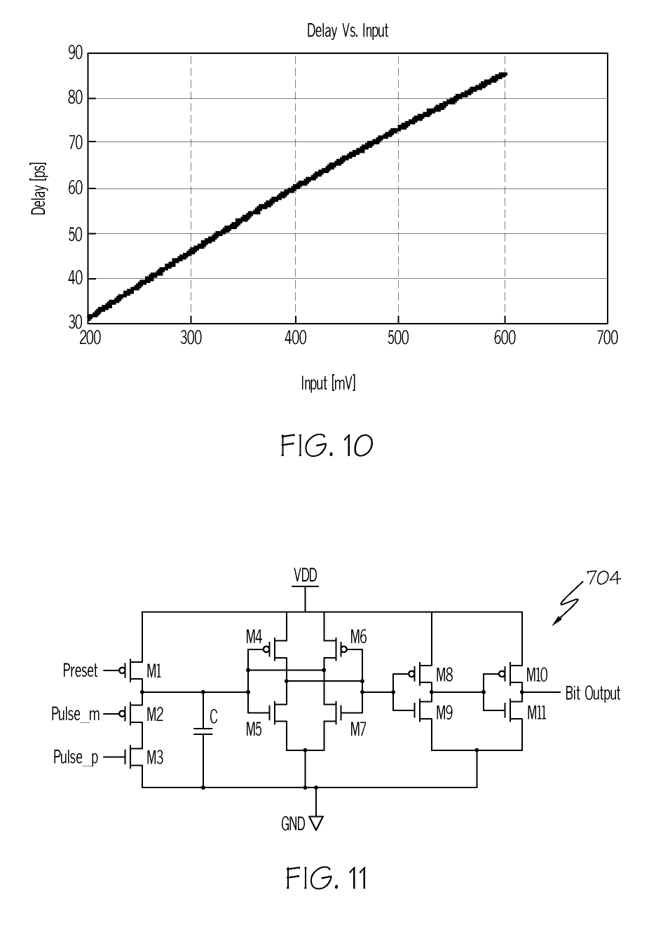

In one embodiment of the present invention, by using interleaved N-block 801 and P-block 802 voltage controlled delay blocks, as illustrated in FIG. 9, a linear transfer function between the input voltage (in millivolts (mv)) and output time delay difference (in picoseconds (ps)) is formed. The linear transfer function is illustrated in FIG. 10 in accordance with an embodiment of the present invention.

Referring to FIG. 11, FIG. 11 illustrates an architecture of a delay comparator 704 (FIG. 7) in accordance with an embodiment of the present invention. As discussed above, in the example for a 6-bit ADC 700, delay comparator 704 of ADC 700 was placed at 63 different locations on transmission lines 702, 703.

Delay comparator 704 may include p-type transistor M1, whose source is coupled to VDD and whose drain is coupled to the source of p-type transistor M2. The gate of p-type transistor M1 is coupled to a preset signal (indicated as “Preset” in FIG. 11). As further illustrated in FIG. 11, the gate of transistor M2 is coupled to the pulse (indicated as Pulse_m” in FIG. 11) from transmission line 702 and the drain of transistor M2 is coupled to the drain of n-type transistor M3. The gate of n-type transistor M3 is coupled to the pulse (indicated as “Pulse_p” in FIG. 11) from transmission line 703 and the source of n-type transistor M3 is coupled to ground (indicated as “GND” in FIG. 11).

As further illustrated in FIG. 11, a capacitor, indicated as “C,” is coupled between the drain of p-type transistor M1 and ground. Further, delay comparator includes a latch structure comprised of transistors M4, M5, M6 and M7. The sources of p-type transistors M4 and M6 are coupled to VDD and the gates of transistors M4 and M6 are tied to the gates of n-type transistors M5 and M7. The drains of transistors M4 and M6 are coupled to the drains of transistors M5 and M7. The sources of transistors M5 and M7 are coupled to ground.

Delay comparator 704 further includes an output buffer comprised of transistors M8, M9, M10 and M11. The source of p-type transistor M8 is coupled to VDD and the gate of transistor M8 is coupled to the gate of transistor M6 as well as to the gate of n-type transistor M9. The drain of transistor M8 is coupled to the drain of transistor M9. Further, the source of transistor M9 is coupled to ground and to the source of n-type transistor M11. The source of p-type transistor M10 is coupled to VDD and the gate of transistor M110 is coupled to the drains of transistors M8, M9 as well as to the gate of transistor M11. The source of M1 is coupled to ground and to the drain of transistor M9. Further, the drains of transistors M10, M11 are coupled to the bit output (indicated as “Bit Output” in FIG. 11) of delay comparator 704.

Prior to the arrival of a pulse, the capacitor C is pre-charged through M1 to VDD using the preset port and accordingly the bit out is set to GND which is the default value for all comparators in the system. After the two differential pulses reach the input of comparator 704, if there is any delay between the pulse edges, transistors M2 and M3 are both turned on and subsequently discharge capacitor C. The switching threshold of delay comparator 704 is determined by the latch structure, formed by transistors M4 through M7. If the pulse edges have sufficient delay (130 ps in this design), the voltage on C can be pulled down enough that the latch changes its state. In this case, the output of comparator 704 becomes VDD. In this design transistors M8 through M11 were the output buffer to drive the encoder (element 706 of FIG. 7) input.

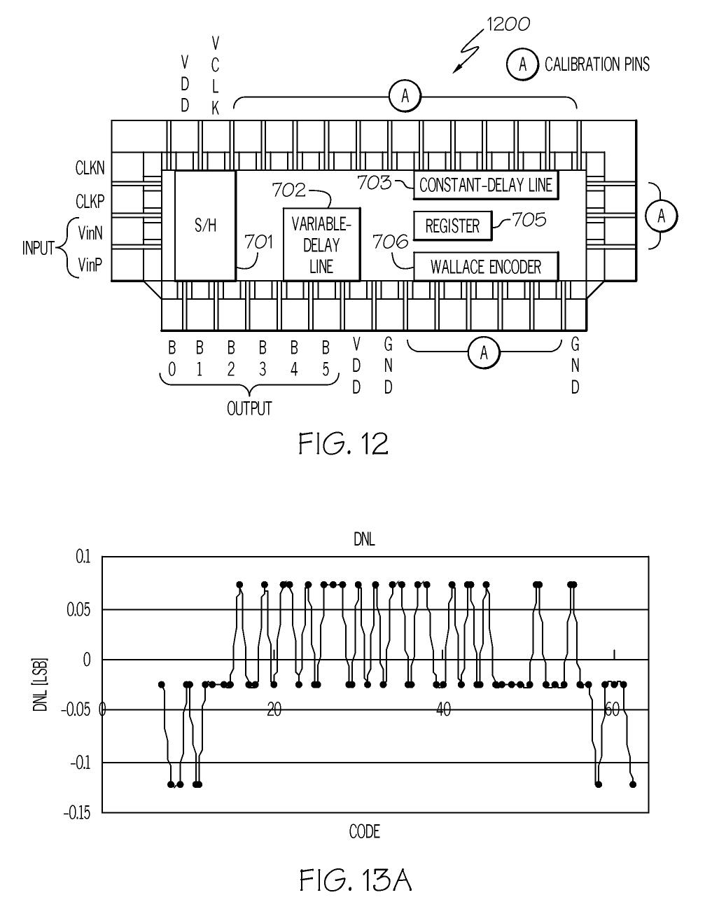

FIG. 12 is a photo of the die 1200 of ADC system 700 (FIG. 7) built using a standard 0.13 μm digital CMOS process in accordance with an embodiment of the present invention. It is noted that delay comparator 704 of FIG. 7 is not depicted in die 1200 for ease of understanding; however, it is included in die 1200. Die 1200 of system 700 has approximately 1.6 mm² area. Calibration pins are used to calibrate ADC system 700. Die 1200 further includes voltage “VDD” and ground “GND” pins. Various clock signals are inputted to clock pins (“CLKN,” “CLKP,” “VCLK”). Input signals are inputted to input pins (“VᵢₙN,” “VᵢₙP”). ADC system 700 is outputted through output pins (B0-B5). It is noted that various pins (e.g., calibration pins, ground (“GND”) pins, voltage (“VDD”) pins, clock pins (“CLKN,” “CLKP,” “VCLK”), inputs (“VᵢₙN,” “VᵢₙP”), outputs (B0-B5)) of die 1200 are not discussed herein in detail for the sake of brevity and for ease of understanding.

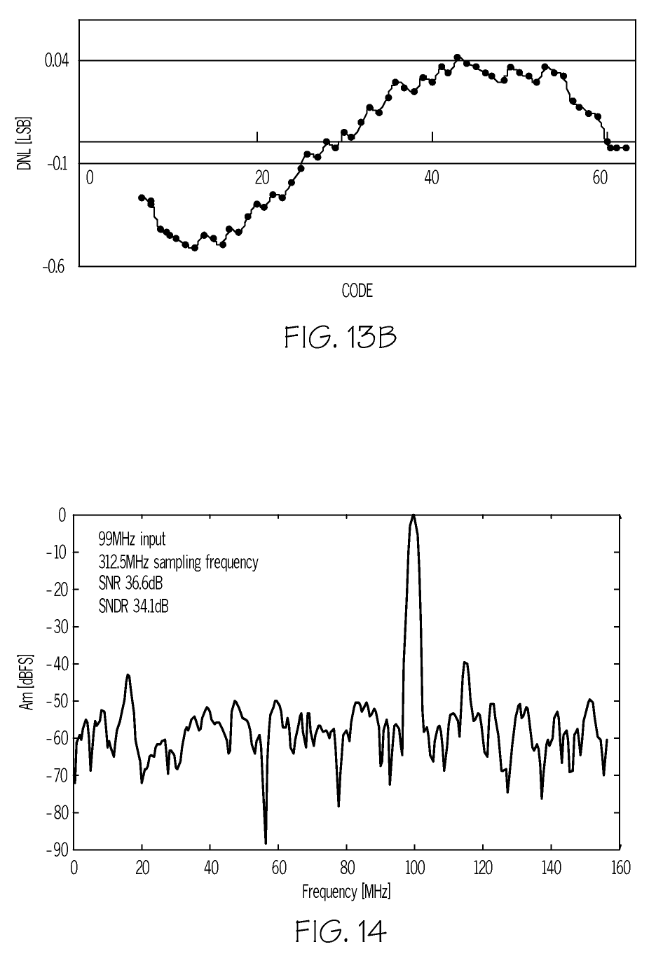

FIG. 13A depicts a graph illustrating the differential (“DNL”) of ADC system 700 (FIG. 7) in accordance with an embodiment of the present invention. FIG. 13B depicts a graph illustrating the integral nonlinearity (“INL”) of ADC system 700 (FIG. 7) in accordance with an embodiment of the present invention. FIG. 14 depicts a graph illustrating the dynamic performance of the ADC system 700 (FIG. 7) in accordance with an embodiment of the present invention. In the analysis of the 6-bit ADC 700, ADC 700 can work up to speeds of 300M samples/s. In addition, the results showed 36.6 dB SNR, 34.1 dB SNDR for a 99 MHz input, DNL<0.2 LSB and INL<0.5 LSB. The overall power consumption (including digital) is 2.7 mW with a 1.2V power supply.

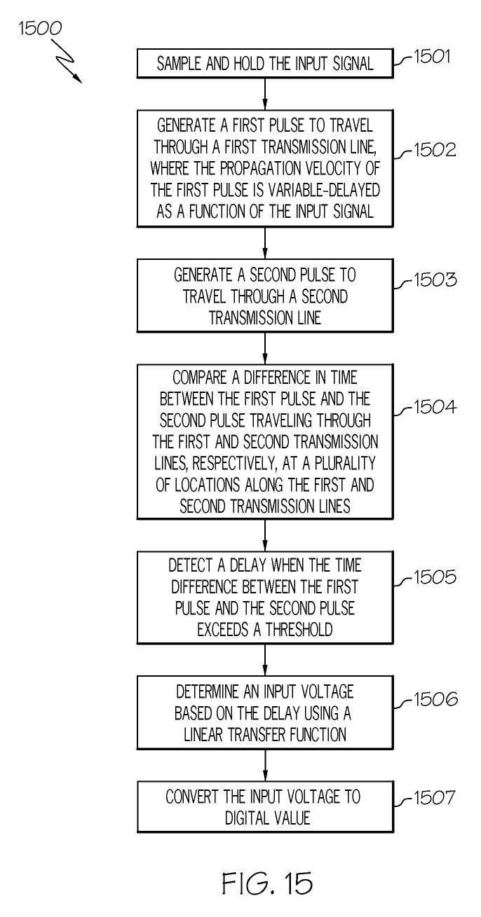

A method for converting an analog signal into a digital value using the principles of the present invention discussed above will now be discussed in conjunction with FIG. 15. FIG. 15 is a flowchart of a method 1500 for converting an analog signal into a digital value in accordance with an embodiment of the present invention.

Referring to FIG. 15, in step 1501, the input signal is sampled and held, such as by sample and hold circuit 701.

In step 1502, a first pulse is generated to travel through a first transmission line (e.g., variable delay transmission line 101), where the first transmission line is a variable-delay transmission line and the propagation velocity of the first pulse is variable-delayed as a function of the input signal.

In step 1503, a second pulse is generated to travel through a second transmission line (e.g., reference transmission line 102), where the propagation velocity of the second pulse is independent of the input signal.

In step 1504, a comparison is made, such as by delay comparator 704, of the difference in time between the first pulse and the second pulse traveling through the first and second transmission lines, respectively, at a plurality of locations along the first and second transmission lines.

In step 1505, a delay is detected when the time difference between the first pulse and the second pulse exceeds a threshold. For example, as discussed in conjunction with ADC 700, delay comparator 704 outputs a digital value of 1 when the delay is greater than a particular time duration threshold (e.g., 120 ps). The delay, when delay comparator 704 outputs a digital value of 1, is used to determine the input voltage as discussed in the next step.

In step 1506, the input voltage is determined based on the delay using the linear transfer function as illustrated in FIG. 10.

In step 1507, the input voltage is converted to a digital value as is well known in the art.

Method 1500 may include other and/or additional steps that, for clarity, are not depicted. Further, method 1500 may be executed in a different order presented and that the order presented in the discussion of FIG. 15 is illustrative. Additionally, certain steps in method 1500 may be executed in a substantially simultaneous manner or may be omitted.

What is claimed is:

1. A method for converting an analog signal into a digital value comprising:
generating a first pulse to travel through a first transmission line, wherein said first transmission is a variable-delay transmission line, wherein a propagation velocity of said first pulse is variable-delayed as a function of an input signal;
generating a second pulse to travel through a second transmission line, wherein a propagation velocity of said second pulse is independent of said input signal;
comparing a difference in time between said first pulse and said second pulse traveling through said first and second transmission lines, respectively, at a plurality of locations along said first and second transmission lines;
detecting a delay when said time difference between said first pulse and said second pulse exceeds a threshold;
determining an input voltage based on said delay; and
converting said input voltage to a digital value.

2. The method as recited in claim 1, wherein said first transmission line comprises active devices.

3. The method as recited in claim 1, wherein said first transmission line comprises passive devices.

4. The method as recited in claim 3, wherein said passive devices comprises shunt varactors.

5. The method as recited in claim 1, wherein said first transmission line is an inhomogeneous transmission line.

6. The method as recited in claim 1, wherein said comparison step is performed by a plurality of comparators located at said plurality of locations along said first and second transmission lines.

7. The method as recited in claim 1, wherein said second transmission line is a variable-delay transmission line, wherein said input signal is applied with reverse polarity to said first and said second transmission lines, respectively.

8. The method as recited in claim 7, wherein said propagation velocity of said first pulse is increased while a propagation velocity of said second pulse is decreased.

9. The method as recited in claim 7, wherein said propagation velocity of said first pulse is decreased while a propagation velocity of said second pulse is increased.

10. The method as recited in claim 1 further comprising:
sampling and holding said input signal.

11. A device for converting an analog signal into a digital value comprising:
a first transmission line, wherein a first pulse travels through said first transmission line, wherein said first transmission is a variable-delay transmission line, wherein a propagation velocity of said first pulse is variable-delayed as a function of an input signal;
a second transmission line, wherein a second pulse travels through said second transmission line, wherein a propagation velocity of said second pulse is independent of said input signal;
a plurality of comparators coupled to said first and second transmission lines at a plurality of locations along said first and second transmission lines, wherein said plurality of comparators compare a difference in time between said first pulse and said second pulse traveling through said first and second transmission lines, respectively, at said plurality of locations along said first and second transmission lines;
circuitry for detecting a delay when said time difference between said first pulse and said second pulse exceeds a threshold; and
circuitry for determining an input voltage based on said delay.

12. The device as recited in claim 11, wherein said first transmission line comprises active devices.

13. The device as recited in claim 11, wherein said first transmission line comprises passive devices.

14. The device as recited in claim 13, wherein said passive devices comprises shunt varactors.

15. The device as recited in claim 11, wherein said first transmission line is an inhomogeneous transmission line.

16. The device as recited in claim 11, wherein said second transmission line is a variable-delay transmission line, wherein said input signal is applied with reverse polarity to said first and said second transmission lines, respectively.

17. The device as recited in claim 16, wherein said propagation velocity of said first pulse is increased while a propagation velocity of said second pulse is decreased.

18. The device as recited in claim 16, wherein said propagation velocity of said first pulse is decreased while a propagation velocity of said second pulse is increased.

19. The device as recited in claim 11 further comprises:
a sample and hold circuit coupled to said first and second transmission lines, wherein said sample and hold circuit is configured to sample and hold said input signal.

20. The device as recited in claim 11, wherein the device is built in an integrated circuit.

21. The device as recited in claim 20, wherein said integrated circuit comprises CMOS technology.
